(19) United States
(12) Patent Application Publication
(10) Pub. No.: US 2023/0360950 A1
(43) Pub. Date: Nov. 9, 2023

(54) GANG-FLIPPING OF DIES PRIOR TO BONDING

(71) Applicant: ADEIA SEMICONDUCTOR BONDING TECHNOLOGIES INC., San Jose, CA (US)

(72) Inventor: Guilian Gao, San Jose, CA (US)

(21) Appl. No.: 17/662,180

(22) Filed: May 5, 2022

(51) Int. Cl. H01L 21/683; H01L 23/00

(52) U.S. Cl. CPC H01L 21/6838; H01L 21/6833; H01L 24/80; H01L 21/6836; H01L 2221/68327; H01L 2221/68368; H01L 2224/8018; H01L 2224/8082; H01L 2224/80896; H01L 2224/80905; H01L 2224/80009; H01L 24/08; H01L 2224/08225; H01L 24/05; H01L 2224/05647

(57) ABSTRACT

Embodiments of various systems, methods, and devices for gang flipping and individual picking dies are disclosed. The embodiments disclosed herein may be used, for example, in the manufacture of directly bonded devices.

### BACKGROUND

### Field

The field relates to methods for directly bonding semiconductor dies and tools for the same. In particular, some embodiments relate to systems and methods for flipping dies prior to bonding.

### Description

Direct bonding can be used in various types of electronics applications to form stacked structures, systems on chip (SoC), microelectromechanical systems (MEMS) devices, optical devices, memory and/or processing devices, etc. The costs associated with surface contamination are especially pronounced when direct bonding is used. Because the direct bonding process joins elements with planarized surfaces without intervening adhesives, even a small number of small particles can have detrimental effects. For example, particles on a bonding surface may lead to voids, which may result in, for example, non-functional interconnects, resistive interconnects that limit performance, or fragility that reduces the useful life of a device.

### SUMMARY

For purposes of this summary, certain aspects, advantages, and novel features are described herein. It is to be understood that not necessarily all such advantages may be achieved in accordance with any particular embodiments.

In some embodiments, the techniques described herein relate to a method including: providing a first wafer and a second wafer; polishing the first wafer and the second wafer; dicing the first wafer on a dicing tape to form a diced wafer comprising a plurality of dies; activating at least one of the first wafer, the diced wafer, and the second wafer; flipping the diced wafer; securing the diced wafer to a chuck; removing the dicing tape from the diced wafer; and bonding at least some of the dies of the plurality of dies to the second wafer. In some embodiments, activating comprises activating the second wafer and one of the first wafer and the diced wafer. In some embodiments, activating comprises exposing the at least one of the first wafer, the diced wafer, and the second wafer to a nitrogen plasma.

In some embodiments, the techniques described herein relate to a method including: providing a plurality of semiconductor dies on a dicing tape, each semiconductor die of the plurality of semiconductor dies having a first bonding surface and a second surface opposite the first bonding surface, the second surfaces of the plurality of semiconductor dies being attached to the dicing tape; and securing the first bonding surfaces of the plurality of semiconductor dies to a chuck while the plurality of semiconductor dies are attached to the dicing tape. In some embodiments, the second surface of each semiconductor die of the plurality of semiconductor dies is a second bonding surface. In some embodiments, the method further comprises preparing the second bonding surface for bonding.

In some embodiments, a method further comprises activating the first bonding surface for direct bonding. In some embodiments, a method further comprises cleaning the first bonding surface.

In some embodiments, the techniques described herein relate to a method, wherein providing the plurality of semiconductor dies includes securing a wafer on the dicing tape and dicing the wafer into the plurality of semiconductor dies.

In some embodiments, the techniques described herein relate to a method, further including: removing the dicing tape from the plurality of semiconductor dies; removing a semiconductor die of the plurality of semiconductor dies from the chuck; and directly bonding the first bonding surface of the semiconductor die to a carrier without an intervening adhesive.

In some embodiments, the techniques described herein relate to a method, wherein the directly bonding includes directly bonding a non-conductive layer of the semiconductor die to a non-conductive layer of the carrier.

In some embodiments, the techniques described herein relate to a method, wherein the directly bonding further includes directly bonding conductive contacts of the semiconductor die to conductive contacts of the carrier.

In some embodiments, the techniques described herein relate to a method, further including: after the directly bonding, cleaning the second surface of the semiconductor die.

In some embodiments, the techniques described herein relate to a method, wherein the second surface is a second bonding surface, further including: after the directly bonding, directly bonding a second semiconductor die to the second bonding surface of the semiconductor die.

In some embodiments, the techniques described herein relate to a method, further including: removing the dicing tape from the plurality of semiconductor dies; and selectively releasing one or more semiconductor dies of the plurality of semiconductor dies while the remaining semiconductor dies of the plurality of semiconductor dies are secured to the chuck.

In some embodiments, the techniques described herein relate to a method, wherein selectively releasing includes selectively releasing only one semiconductor die.

In some embodiments, the techniques described herein relate to a method, wherein the chuck is an electrostatic chuck, and wherein securing includes: applying, by the electrostatic chuck, an electrostatic force to the plurality of semiconductor dies, wherein applying an electrostatic force includes suppling power to a plurality of electrodes embedded in the electrostatic chuck.

In some embodiments, the techniques described herein relate to a method, further including: removing the dicing tape from the plurality of semiconductor dies; and selectively releasing one or more semiconductor dies of the plurality of semiconductor dies while the remaining semiconductor dies of the plurality of semiconductor dies are secured to the electrostatic chuck, wherein selectively releasing includes changing the power supplied to one or more electrodes of the plurality of electrodes.

In some embodiments, the techniques described herein relate to a method, wherein changing the power supplied includes inverting a polarity of the power supplied to the one or more electrodes.

In some embodiments, the techniques described herein relate to a method, wherein the chuck is a vacuum chuck, and wherein securing includes: applying a vacuum force to the plurality of semiconductor dies via a plurality of vacuum channels embedded in the vacuum chuck.

In some embodiments, the techniques described herein relate to a method, further including: removing the dicing tape from the plurality of semiconductor dies; and selectively releasing one or more semiconductor dies of the plurality of semiconductor dies while the remaining semiconductor dies of the plurality of semiconductor dies are secured to the vacuum chuck.

In some embodiments, the techniques described herein relate to a method, wherein selectively releasing includes reducing a vacuum force applied to the one or more semiconductor dies.

In some embodiments, the techniques described herein relate to a method, wherein a plurality of porous inserts are disposed on top of the plurality of vacuum channels.

In some embodiments, the techniques described herein relate to a method, wherein the plurality of semiconductor dies are disposed on top of the plurality of porous inserts.

In some embodiments, the techniques described herein relate to a method, wherein providing includes: applying a protective layer to a wafer; mounting the wafer on the dicing tape; and dicing the wafer into a plurality of semiconductor dies.

In some embodiments, the techniques described herein relate to a method, wherein providing further includes, after dicing, removing the protective layer from the plurality of semiconductor dies.

In some embodiments, the techniques described herein relate to a method, further including: prior to securing, activating the first bonding surface while the dies are attached to the dicing tape.

In some embodiments, the techniques described herein relate to a method, wherein activating is performed after dicing a wafer to form a plurality of semiconductor dies.

In some embodiments, the techniques described herein relate to a method, wherein activating includes exposing the first bonding surface to a nitrogen-containing plasma.

In some embodiments, the techniques described herein relate to a method, further including planarizing at least one of the first bonding surface and the second surface prior to securing a wafer to the dicing tape.

In some embodiments, the techniques described herein relate to a method, further including picking, by a vacuum bonding tool, a die of the plurality of dies from the chuck, wherein the vacuum bonding tool is conductive and electrically grounded, and wherein picking includes removing a charge from the die by contacting the die with the conductive vacuum bonding tool.

In some embodiments, the techniques described herein relate to a method including: securing a wafer on a dicing tape; dicing the wafer into a plurality of semiconductor dies, each semiconductor die of the plurality of semiconductor dies having a first bonding surface and a second surface opposite the first bonding surface, the second surfaces of the plurality of semiconductor dies being attached to the dicing tape; securing the first bonding surfaces of the plurality of semiconductor dies to a chuck while the plurality of semiconductor dies are attached to the dicing tape; removing the dicing tape from the plurality of semiconductor dies; and removing a die of the plurality of semiconductor dies from the chuck.

In some embodiments, the techniques described herein relate to a method, further including flipping the plurality of semiconductor dies and the dicing tape.

In some embodiments, the techniques described herein relate to a method, wherein the chuck is an electrostatic chuck, the method further including: applying an electrostatic force to the plurality of semiconductor dies for securing the plurality of semiconductor dies to the electrostatic chuck.

In some embodiments, the techniques described herein relate to a method, wherein removing the die includes reducing the electrostatic force applied to the die by the electrostatic chuck.

In some embodiments, the techniques described herein relate to a method, wherein removing the die includes terminating power supplied to one or more electrodes of the electrostatic chuck associated with the die.

In some embodiments, the techniques described herein relate to a method, wherein removing a die includes inverting the electrostatic force applied by the electrostatic chuck to the die and reducing the electrostatic force applied by the electrostatic chuck to the die.

In some embodiments, the techniques described herein relate to a vacuum chuck for supporting a plurality of semiconductor dies, the vacuum chuck including: a plate including a die support surface comprising a plurality of die support regions; and a plurality of vacuum channels extending through the plate, the plurality of vacuum channels connectable to one or more vacuum sources, each vacuum channel of the plurality of vacuum channels associated with a corresponding die support region. In some embodiments, there is only one vacuum channel associated with each die support region.

In some embodiments, the techniques described herein relate to a vacuum chuck, further including a plurality of porous regions disposed at the die support surface of the plate, each porous region disposed over a corresponding vacuum channel of the plurality of vacuum channels.

In some embodiments, the techniques described herein relate to a vacuum chuck, further including a controller configured to independently control each vacuum channel of the plurality of vacuum channels.

In some embodiments, the techniques described herein relate to a vacuum chuck, wherein the plurality of porous regions include replaceable porous inserts.

In some embodiments, the techniques described herein relate to a vacuum chuck, wherein the porous regions are wider than the corresponding vacuum channel.

In some embodiments, the techniques described herein relate to a vacuum chuck, wherein the porous regions include a polymer coating.

In some embodiments, the techniques described herein relate to an electrostatic chuck for supporting a plurality of semiconductor dies using electrostatic force, the electrostatic chuck including: a non-conductive body having a plurality of die support regions, each die support region configured to support a die of the plurality of semiconductor dies; and a plurality of electrodes in the non-conductive body, each die support region having a first electrode having a first polarity and a second electrode having a second polarity opposite the first polarity associated therewith.

In some embodiments, the techniques described herein relate to an electrostatic chuck, further including a controller configured to independently control each of the electrodes of the plurality of electrodes.

### BRIEF DESCRIPTION OF THE DRAWINGS

These and other features, aspects, and advantages of the disclosure are described with reference to drawings of certain embodiments, which are intended to illustrate, but not to limit, the present disclosure. It will be understood that the accompanying drawings, which are incorporated in and constitute a part of this specification, are for the purpose of illustrating concepts disclosed herein and may not be to scale.

FIG. 1 depicts an example process for individually picking and placing dies according to some embodiments.

FIG. 2 depicts an example process for gang flipping dies according to some embodiments.

FIG. 3 depicts an example vacuum chuck according to some embodiments.

FIGS. 4a-4c depict examples of porous inserts that may use in a vacuum chuck according to some embodiments.

FIG. 5 depicts an example electrostatic chuck according to some embodiments.

FIGS. 6a and 6b depict example electrostatic chuck surfaces according to some embodiments.

FIG. 7 depicts an example process for gang flipping and individually picking dies using an electrostatic chuck and a conductive vacuum bonding tool according to some embodiments.

### DETAILED DESCRIPTION OF CERTAIN EMBODIMENTS

Although several embodiments, examples, and illustrations are disclosed below, it will be understood by those of ordinary skill in the art that the disclosures described herein extend beyond the specifically disclosed embodiments, examples, and illustrations and include other uses and obvious modifications and equivalents thereof. Embodiments are described with reference to the accompanying figures, wherein like numerals refer to like elements throughout. The terminology used in the description presented herein is not intended to be interpreted in any limited or restrictive manner simply because it is being used in conjunction with a detailed description of certain specific embodiments of the inventions. In addition, embodiments of the inventions can comprise several novel features and no single feature is solely responsible for its desirable attributes or is essential to practicing the inventions herein described.

Various embodiments described herein relate to systems and methods for flipping and directly bonding dies. The embodiments described herein may be used in, for example, the manufacture of any suitable type of electronic devices, such as stacked structures, systems on chip (SoC), microelectromechanical systems (MEMS) devices, optical devices, memory and/or processing devices, etc.

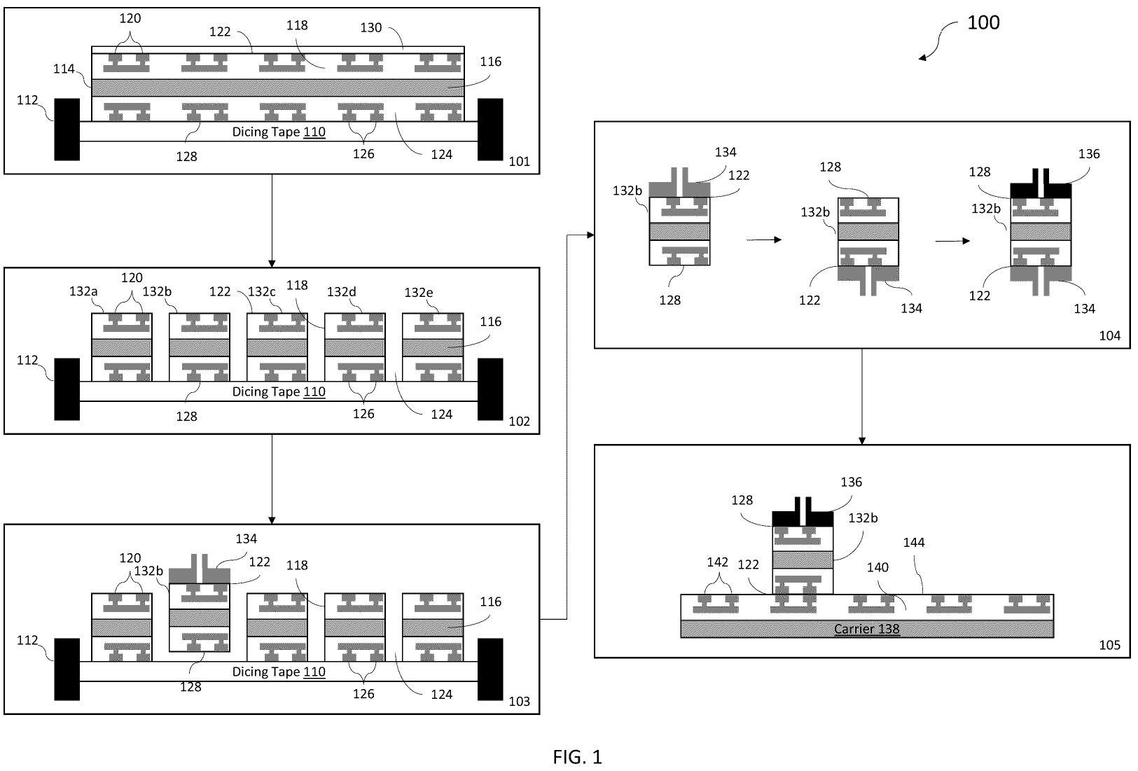

In some embodiments, a direct bonding process may be performed according to the techniques disclosed in at least U.S. Pat. No. 11,037,919, which is incorporated by reference herein in its entirety and for all purposes. FIG. 1 is an example of a direct bonding process flow 100 in which individual dies are picked and placed on a carrier 138 to directly bond one or more of the dies to the carrier 138. At block 101, a device wafer 114 may have a device portion 116 (for example, a semiconductor portion that may be patterned with circuitry), a first bonding layer including a first non-conductive layer 118 and a plurality of first contact features 120 at least partially embedded in the first non-conductive layer 118, a first bonding surface 122 at an exterior (e.g., upper) surface of the first bonding layer, and in some embodiments, a second bonding layer including a second non-conductive layer 124 and a plurality of second contact features 126 at least partially embedded in the second non-conductive layer 124, and a second surface 128 (which can comprise a second bonding surface for multi-die stacking arrangements) at an exterior (e.g., lower) surface of the second bonding layer. As shown in block 101, a protective layer 130 (e.g., a polymer layer such as a photoresist layer) can be provided over the first bonding surface 122. The protective layer 130 can protect the wafer 114 during dicing. The wafer 114 may be disposed on a dicing tape 110 attached to a frame 112. As described herein, the first bonding surface 122 and, in some embodiments, the second surface 128 may be polished to a high degree of smoothness in preparation for direct bonding.

At block 102, the wafer 114 may be diced into a plurality of dies 132a-e. The wafer 114 may be diced in any suitable way, such as saw singulation, laser stealth dicing, reactive ion etching (RIE), or plasma dicing, and so forth. After dicing, the protective layer 130 may be removed by ashing (e.g., exposing to oxygen plasma) and rinsing with deionized (DI) water, by using a suitable solvent, or by any other suitable method. In some embodiments, the protective layer 130 may be a polymer (such as a photoresist layer) that is reactive to ultraviolet light, and the protective layer 130 may be exposed to ultraviolet light prior to removing the protective layer 130. As described herein, the bonding surface 122 of the dies 132a-e can be further processed on the dicing tape 110 in preparation for bonding. For example, the dies 132a-e may be activated (for example, exposed to plasma, such as a nitrogen-containing plasma, or etchants) and/or cleaned in preparation for bonding.

At block 103, a flipping tool 134 (for example, a vacuum flipping tool) may pick a die 132b from the tape for bonding by contacting the first bonding surface 122 of the die 132b. At block 104, the flipping tool 134 may flip the die 132b and the die 132b may be transferred to a bonding tool 136 (for example, a vacuum bonding tool). The bonding tool 136 may contact the second surface 128 of the die 132b. In some embodiments, the second surface 128 can comprise a second bonding surface that is prepared for direct bonding including, for example, a polished non-conductive surface with at least partially embedded conductive contacts. In other embodiments, the second surface 128 may comprise a grinded surface that is not bonded to another element. At block 105, the bonding tool 136 may be used to bond the die 132b to a carrier 138. The carrier may have a non-conductive carrier region with carrier contact features 142 at least partially embedded therein and a carrier bonding surface 144. The first bonding surface 122 of the die 132b may be bonded (i.e., directly bonded) to the carrier bonding surface 144. The carrier 138 may be a wafer, die, interposer, or any other suitable element.

The process depicted in FIG. 1 offers several advantages but also has several limitations. For example, individually picking and bonding dies allows only known-good dies (KGDs) to be picked. Similarly, if there is a known bad portion of the carrier 138, that portion can be avoided so that a KGD is not placed in a known bad portion of the carrier 138. In some cases, the flipping tool 134, which contacts the first bonding surface 122, may become contaminated. In some cases, the flipping tool 134 may be contaminated from previous processing, from wear or defects with the tool, or by picking up particles that are present on the surface of the dies and spreading the particles to other dies. For example, if die 132a is picked up first by the flipping tool 134, any contamination on the first bonding surface 122 of the die 132a may be transferred by the flipping tool 134 to the other dies 132b-e. In some cases, the transfer of contaminants to other dies may render the other dies unusable or cause other problems. Contamination issues can be especially pronounced in the case of large die sizes. For example, for a 300 mm wafer with a 1 cm by 1 cm die size and a defect density of about 0.1 defects per square centimeter, about 10% of dies will have a defect. In contrast, if the die size is about 4 centimeters by 4 centimeters, about 75% of dies will be defective, given the same defect density.

In some cases, such as low volume test runs, it may be practical to clean the surface of the flipping tool frequently, for example after every die, after every tenth die, and so forth. However, in higher volume production use, flipping tools often process thousands of units per hour, rendering it infeasible and expensive to clean the flipping tool between dies. Thus, there is a need for a way to flip dies in preparation for bonding without contaminating the surfaces of the dies.

In some cases, it may be feasible to eliminate the flipping tool that contacts each die by using a collective bonding process. While collective bonding prevents contamination by a flipping tool, if such collective bonding is performed, then dies that are known to be defective cannot be screened out, e.g., KGDs may not be selected. Thus, collective bonding can lead to decreased device yield by including defective dies. An inability to identify and select KGDs can lead to reduced overall yield and increased costs. Screening out bad dies can be especially important when the die size is large so there are fewer dies per wafer. Generally, manufacturing cost is largely independent of the die size, so if there are fewer dies per wafer, the cost of manufacturing each die will be higher. Thus, it is important to ensure that dies that are known to be bad are not bonded to other, good device components.

In addition to the problem of not being able to screen out bad dies, collective bonding can present other challenges. For example, some collective bonding processes include preparing a transfer wafer with an adhesive layer, bonding the dies to the transfer wafer to form a reconstituted wafer, and then carrying out a wafer to wafer bonding process to bond the transfer wafer and a carrier wafer. This process may include one or more cleaning and/or activation steps, after which the transfer wafer is removed.

Collective bonding can be especially problematic when features of the dies are close together (for example, fine pitch electrical interconnects, optical paths, and so forth). Alignment errors may arise from flexibility in the dicing tape, from the placement of dies onto the transfer wafer (if a transfer wafer is used), as well as from alignment of the dicing tape or transfer wafer and the carrier wafer. The compounding effect of the alignment errors can result in reduced yield, reduced device performance, and so forth.

Accordingly, it can be beneficial to flip dies and bond them to another surface without contaminating the surfaces of the dies, while still being able to individually pick and place dies, allowing for the rejection of known-bad dies and reducing the potential for problems due to alignment errors.

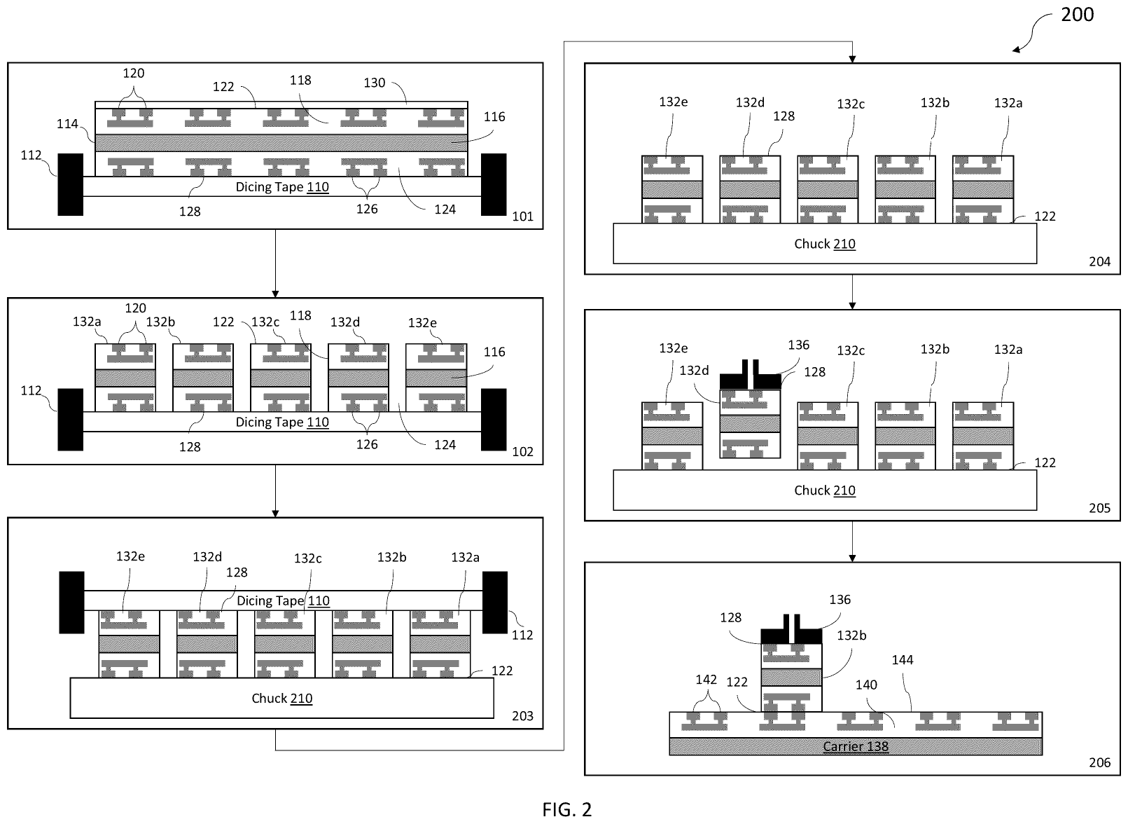

Turning to FIG. 2, an example process 200 for gang flipping dies and individually picking and placing dies on a carrier 138 to directly bond one or more of the dies to the carrier 138 according to some embodiments is depicted. The process flow 200 may be similar in some respects to the process flow 100. For example, blocks 101 and 102 of the process flow 100 may be the same for the process flow 200. At block 101, a device wafer 114 (e.g., a silicon device wafer) may have a device portion 116 (for example, a semiconductor portion that may be patterned with circuitry), a first bonding layer including a first non-conductive layer 118 and a plurality of first contact features 120 at least partially embedded in the first non-conductive layer 118, a first bonding surface 122 at an exterior (e.g., upper surface) of the first bonding layer, and optionally, a second bonding layer including a second non-conductive layer 124 and a plurality of second contact features 126 at least partially embedded in the second non-conductive layer 124, and a second surface 128 at an exterior (e.g., lower) surface of the second bonding layer. The first bonding layer and the second bonding layer may be disposed on opposite sides of the device portion 116. As shown in block 101, the first bonding surface 122 may be coated with a protective layer 130 (e.g., a polymer such as a photoresist layer) that protects the wafer 114 during dicing. The device wafer 114 may be disposed on a dicing tape 110 attached to a frame 112. As described herein, the first bonding surface 122 and, in some embodiments, the second surface 128 may be polished to a high degree of smoothness in preparation for direct bonding.

At block 102, the device wafer 114 can be diced into a plurality of singulated device dies 120 and may undergo further processing in preparation for bonding as described above.

At block 203, the frame 112, dicing tape 110, and diced device wafer 114 (comprising a plurality of device dies 132a-e) is collectively flipped and placed onto a chuck 210. The first bonding surface 122 of the device dies 132a-e are in contact with the surface of the chuck 210. The device dies may be secured (e.g., temporarily or releasably secured) to the chuck 210 by, for example, an electrostatic force or a vacuum force. In some embodiments, instead of flipping the frame 112, dicing tape 110, and device dies 132a-e, the orientation of may remain unchanged and the chuck 210 may be moved into place to contact the dies 132a-e. For example, the chuck 210 may move vertically downward to contact the dies 132a-e.

At block 204, the dicing tape 110 and frame 112 may be pulled away from the dies 132a-e, exposing the second surface 128. The force applied by the chuck 210 to the dies 132a-e may be greater than the adhesive force of the dicing tape 110, allowing the dicing tape 110 to be removed while the dies 132a-e remain affixed to the chuck 210. In some embodiments, the dicing tape 110 may be a UV release tape, such that it can be removed relatively easily after exposure to ultraviolet light. For example, commercially available UV release tape may decrease in adhesion strength by about one order magnitude or about two orders of magnitude after UV exposure. In some cases, the dicing tape 110 may be removed at an acute angle with respect to the second surface 128, which can optionally be a second bonding surface. This may reduce the downward electrostatic or vacuum force needed to hold the dies 132a-e in place on the chuck 210.

At block 205, a bonding tool 136 (for example, a vacuum bonding tool) may pick a die (for example, the die 132d) from the chuck in preparation for bonding. In some embodiments, the die 132d may comprise a known good die (KGD). The bonding tool 136 may contact the second surface 128 of the die 132d. At block 206, the die 132b may be bonded (i.e., directly bonded) to a carrier 138 having a non-conductive carrier region 140 with carrier contact features 142 that are at least partially embedded in the non-conductive carrier region 140. The carrier may have a carrier bonding surface 144, and the die 132b may be bonded (i.e., directly bonded) to the carrier 138 via the carrier bonding surface 144 and the first bonding surface 122 of the die 132b.

The process 200 offers several advantages. As discussed above, an individual picking and placing process (for example, as shown in FIG. 1) can lead to contamination due to the flipping tool making sequential contact with multiple dies. The process 200 eliminates the flipping tool that makes contact with the first bonding surface of each die. Rather, the process includes collectively flipping the plurality of dies on a dicing tape and transferring them to a clean chuck, ensuring that the first bonding surface remains clean. In some embodiments, the chuck may be cleaned after each use. This may lead to increased yield, improved device performance, and so forth. Advantageously, the process 200 allows individual dies to picked, so that only KGDs may be selected, thereby improving yield.

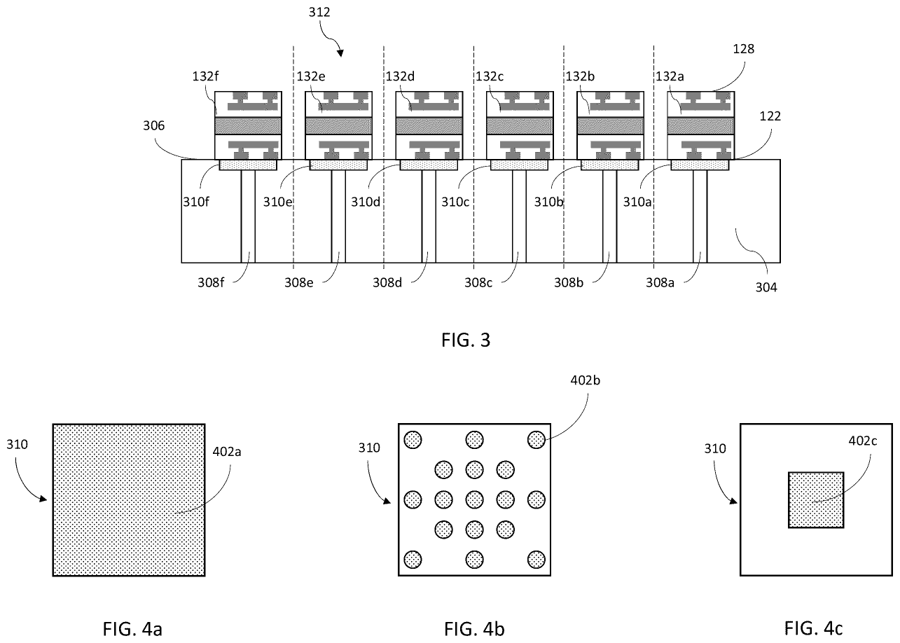

As discussed above, the process 200 may be carried out using, for example, a vacuum chuck or an electrostatic chuck. Preferably, a chuck allows individual dies, or groups of dies, to be released while other dies or groups of dies remain affixed to the surface of the chuck. FIG. 3 depicts a vacuum chuck 304 according to some embodiments. The vacuum chuck 304 has a die support surface 306 comprising a plurality of die support regions 312 (indicated by dashed lines) that are sized and shaped to receive a corresponding die and a plurality of vacuum channels 308a-f for applying a vacuum force on each die 132a-f. In some embodiments, the die support regions can be delineated by markings or other indicia. In some embodiments, there may be more than one vacuum channel per die support region. In other embodiments, there may be exactly one vacuum channel per die support region. In one embodiment, the support surface is a single piece of material with vacuum hole patterns to hold each die in place. In another embodiment, a plurality of porous inserts 310a-f fitting to the end of each vacuum channel 308a-f, each insert corresponding to a vacuum channel. The porous inserts 310 may be, for example, a porous ceramic material, such as might be used in grinding processes. The porous inserts 310 may shed particles. Thus, in some embodiments, the surface of the porous inserts 310 may be coated to prevent shedding of particles. For example, in some embodiments, the surface may be coated with a polyimide material, such as a vacuum deposited polyimide film. In some embodiments, rather than using a porous ceramic material, which may scratch the surfaces of the dies 132a-f, a porous polymer material, such as various porous polymer media from Porex Filtration Group of Fairburn, GA and the ultrahigh-molecular-weight polyethylene porous film SUNMAP™ from Nitto Denko Corporation of Osaka, Japan, may be used.

The first bonding surface 122 of the dies 132a-f may be in contact with the vacuum chuck 304. The dies 132a-f may be placed in contact with the porous inserts 310a-f, which may be smaller than (e.g., slightly smaller than) the size of the dies 132a-f. In other embodiments, the inserts 310a-310f are approximately the same size as the size of the dies 132a-132f,

Advantageously, the vacuum force applied to each of the dies 132a-f may be independently controlled, allowing for an individual die to be picked up with a bonding tool while the other dies remain fixed in place. As just one example, die 132a may be removed for bonding while dies 132b-f remain on the chuck 304. A controller (not shown) can be configured to selectively deactivate the vacuum force to channel 308a to allow die 132a to be released (for example, by operating a valve that prevents communication between a vacuum source (e.g., a vacuum pump) and the channel 308a) while maintaining the vacuum force to channels 308b-f such that the dies 132b-f remain affixed to the surface of the vacuum chuck 304.

In some embodiments, the porous inserts 310a-f may be flush with the top surface of the vacuum chuck 304. In other embodiments, the porous inserts 310a-f may be recessed from the top surface of the vacuum chuck 304. For example, a slight recess may prevent the dies 132a-f from making physical contact with the porous insert 310.

In some embodiments, a purge gas may be used to limit the accumulation of particles on the surface of the vacuum chuck 304. For example, after each die of the plurality of dies 132a-f has been removed from the vacuum chuck 304, or prior to placing the dies 132a-f onto the vacuum chuck 304, or both, an inert gas may be flowed through the vacuum channels 308a-f and the porous inserts 310a-f. For example, in some embodiments, a system may be configured to flow argon or nitrogen gas through the channels 308a-f and the porous inserts 310a-f.

In some embodiments, the porous inserts 310a-f may be selected so that the porous surface 402a-c is proportional to the size of the dies 132a-f. For example, in some embodiments, the porous surface 402a-c may be about the same size and/or shape (e.g., slightly smaller than) the size and/or shape of the dies 132a-f. Beneficially, the porous inserts 310a-f can laterally distribute the vacuum forces across the first bonding surface 122 of the dies 132a-f, which can reduce stresses that may be imparted by a narrowly-applied vacuum force. This may, for example, reduce stresses on the dies 132a-f that could lead to cracking or other failures. In some cases, the porous inserts 310a-f may be replaceable so that the chuck may be used for different die sizes. FIGS. 4a-4c depict examples of porous inserts 310 with porous areas 402a-c of different sizes and shapes to accommodate different dies. As shown in FIG. 4a, the porous area 402a may be the same size as the porous insert, and the insert may be sized and shape for a particular die geometry. FIG. 4b depicts an alternative arrangement in which the insert contains a plurality porous areas 402b in a patterned arrangement. In some cases, the porous area 402c may be smaller than the insert, as depicted in FIG. 4c, for example for a small die.

In some embodiments, a large thin die, such as a DRAM die, may benefit from the use of porous inserts which may enable more uniform application of vacuum force across the die area. In some embodiments, a die may be robust enough that the die may be placed directly on the surface of the chuck, for example a graphical processing unit (GPU) or central processing unit (CPU) die may have sufficient thickness (for example, 200 um or thicker). In some embodiments, a vacuum chuck may have vacuum channels but may not have porous inserts. For example, rather than having porous inserts, in some embodiments vacuum channels may extend to the surface of the chuck. In some embodiments, the surface of the chuck may have an array of vacuum holes. In other embodiments, the surface of the chuck may have vacuum channels, for example recesses in the surface of the chuck to enable the application of vacuum force to dies disposed on the chuck. In some embodiments, the surface of the chuck may be coated with an organic coating such as a polyimide to prevent scratching and/or contamination of the bonding surface.

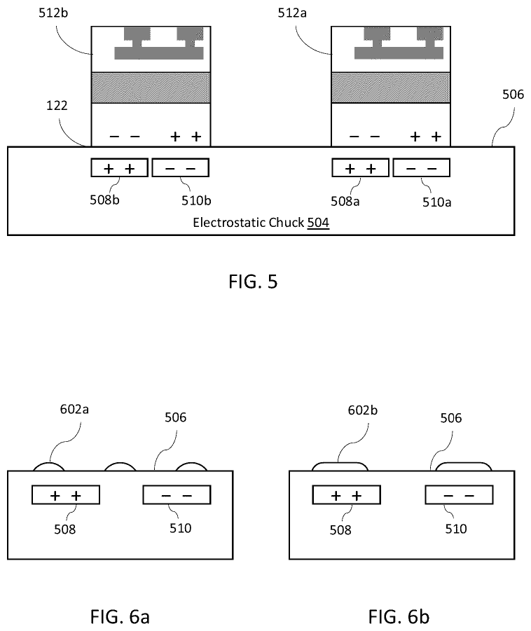

In some cases, rather than a vacuum chuck, such as the vacuum chuck 304 depicted in FIG. 3, an electrostatic chuck 504 may be used to hold the dies 512a,b (which may be, for example, dies 132a,b) in place during dicing tape removal and picking. FIG. 5 depicts an example electrostatic chuck 504 according to some embodiments. In FIG. 5, the first bonding surface 122 the dies 512a,b is placed onto a die support surface 506 of the electrostatic chuck 504. The electrostatic chuck 504 has electrodes 508a,b and 510a,b for the dies 512a,b, each pair of electrodes corresponding to a die (for example, electrodes 508a and 510a may correspond to the die 512a). The electrodes 508a, b and 510a,b may be connected to a power supply (not shown) and a voltage on the order of tens to thousands of volts may be applied, depending on the chuck construction and the force required to hold the die flat for removal of the dicing tape. The electrostatic chuck 504 may be made of a non-conductive dielectric material such as alumina, silicon oxide, a polyimide, etc. with metal electrodes and so forth. In some cases, the surface of the electrostatic chuck may be coated with a coating that does not directly bond to the dies. For example, the electrostatic chuck 504 can be coated with a polymer (e.g., polyimide), or other suitable coating. For example, the mobile electrostatic chucks available from Eshylon Scientific of Pleasanton, CA, are constructed on a silicon substrate and coated with a polyimide surface layer.

In some embodiments, the surface may be textured or patterned to reduce the contact area between a die and the die support surface 506 of the electrostatic chuck 504. FIGS. 6a and 6b depict example embodiments of textured surfaces that reduce contact between a first bonding surface 122 and the electrostatic chuck 504. For example, the features 602a shown in FIG. 6a may reduce the surface area of the die that is in contact with the chuck (i.e., the die may contact the chuck only at the peaks of the features 602a). As another example, the features 602b shown in FIG. 6b may limit contact between the first bonding surface 122 and the electrostatic chuck 504. The flat surface of the features 602b may reduce stresses in the die relative to the small contact area of the features 602a. FIGS. 6a and 6b are merely examples, and other patterns may be used. In some cases, the texture of the electrostatic chuck surface may be random or may be designed for a particular die shape and size (for example, designed to minimize contact with critical areas on the die).

While FIG. 5 shows a bipolar configuration with two electrodes for each die 512a and 512b, other configurations are also possible. For example, instead of a bipolar configuration, a monopolar configuration could be used, where each die has only a single electrode associated with it. In some embodiments, rather than having electrodes for each die, the same electrode or electrodes may be used for multiple dies. In some embodiments, there may be only a single electrode (for example, for a monopolar electrostatic chuck) or two electrodes (for a bipolar chuck) for all the dies that are to be gripped to the surface of the chuck.

In some embodiments, the electrodes 508a,b and 510a,b may be in communication with a controller (not shown) that can selectively supply or deactivate power to the electrodes. For example, a controller may be configured to turn off power to electrodes 508a and 510a so that the die 512a can be removed from the electrostatic chuck 504 (e.g., by a bonding tool such as the bonding tool 136), while maintaining power to electrodes 508b and 510b so that the die 512b remains affixed to the electrostatic chuck 504. In some embodiments, rather than (or in addition to) turning off power, the controller may invert power supplied to the electrodes 508a and 510a.

In some embodiments, the power supplied to the electrodes may be large during some parts of a process (for example, when removing dicing tape from dies or when performing a plasma cleaning process). At other times, the power supplied may be small so that there is only a small electrostatic force keeping the dies in place, for example during picking of the die from the tape for bonding. When power to the electrodes of the chuck is terminated, the dies typically will remain bound to the chuck for some time due to a remaining charge in the die and in the dielectric material of the chuck. While eventually the residual charges will dissipate, advantageously the dies may remain bound long enough for a picking process to complete.

While remaining residual charge can be useful for keeping dies in place during further manipulations (e.g., picking), it also presents significant problems. For example, it may be difficult to remove a die from the chuck using a vacuum bonding tool without cracking or breaking the die. In some cases, lift pins or other mechanical devices may be used to lift the die away from the chuck, but this can also crack or break the die. The use of lift pins, for example, can also cause the die to pop off the chuck unpredictably. This can be especially problematic because the electrostatic force keeping the die affixed to the chuck varies over time, making it difficult to determine the appropriate lift force to use to remove the die from the chuck. In some cases, dies may be released by inverting the electrostatic force. However, this can also be problematic because it may be important to know the electrostatic force that is keeping the die affixed to the chuck in order to determine an amount of force to apply (i.e., what voltage to apply to the electrodes).

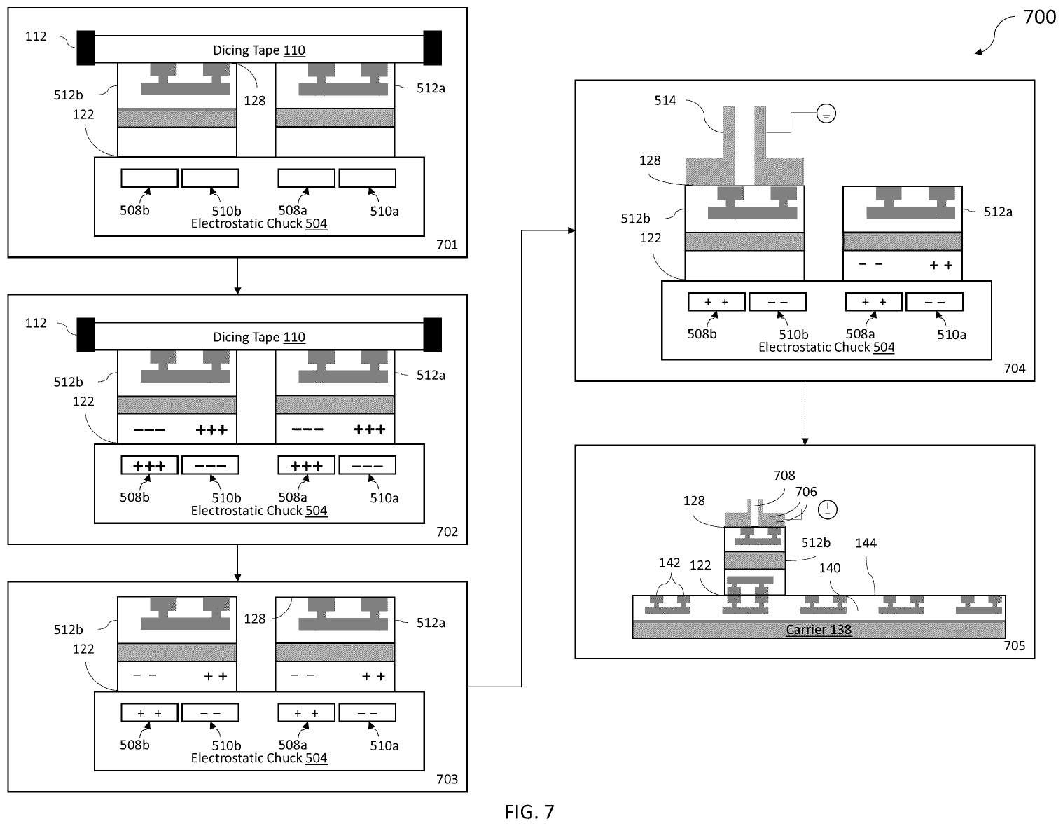

FIG. 7 depicts a process 700 for collectively flipping dies 512a,b (which may be, for example, dies 132a,b as shown in FIG. 1) onto an electrostatic chuck 504 and removing dies individually (or in selected subgroups) from the electrostatic chuck 504 according to some embodiments. Prior to block 701, dies may be singulated and prepared for bonding, for example as described in blocks 101 and 102 of FIG. 1.

At block 701, dies 512a, b may be affixed to a dicing tape 110 supported by a frame 112 are collectively flipped onto an electrostatic chuck 504, the dies 512a,b contacting the chuck via a first bonding surface 122. At block 702, power may be supplied to the electrodes 508a,b and 510a,b and the dies 512a,b may be electrostatically held to the surface of the electrostatic chuck 504. The dicing tape 110 may be removed from the dies 512a,b. In some embodiments, removing the dicing tape 110 may comprise exposing the dicing tape to ultraviolet light prior to and/or while pulling the tape away from the dies 512a,b. At block 703, power may be reduced to the electrodes 508a,b and 510a,b so that the dies 512a,b are held in place with less electrostatic force than was applied while removing the dicing tape 110. In some embodiments, power to the electrodes 508a,b and 510a,b may be lowered or completely turned off, and residual charge in the electrostatic chuck 504 (e.g., in a non-conductive region of the electrostatic chuck 504) and the dies 512a,b may be used to keep the dies 512a,b in place.

At block 704, a bonding tool 706 may be used to pick an individual die (e.g., die 512b) from the surface of the electrostatic chuck 504 by contacting the second surface 128 of the die 512b. In the illustrated embodiment, the bonding tool 706 can comprise a vacuum bonding tool having a vacuum channel 708. Advantageously, the bonding tool 706 can be conductive and connected to electrical ground. Thus, by grounding the bonding tool 706, when the bonding tool contacts the die 512b, charge in the die 512b may be dissipated and the die 512b may be picked from the surface of the electrostatic chuck 504 without damaging the die 512b. At block 705, the die 512b may be bonded (i.e., directly bonded) to carrier 138 via the carrier bonding surface 144 and the first bonding surface 122 of the die 512b.

### Examples of Direct Bonding Methods and Directly Bonded Structures

Various embodiments disclosed herein relate to directly bonded structures in which two elements can be directly bonded to one another without an intervening adhesive. Two or more semiconductor elements, such as integrated device dies, wafers, and other semiconductor elements, may be stacked on or bonded to one another to form a bonded structure. Conductive contact pads of one element may be electrically connected to corresponding conductive contact pads of another element. Any suitable number of elements can be stacked in the bonded structure.

In some embodiments, the elements are directly bonded to one another without an adhesive. In various embodiments, a non-conductive or dielectric material of a first element can be directly bonded to a corresponding non-conductive or dielectric field region of a second element without an adhesive. The non-conductive material can be referred to as a non-conductive bonding region or bonding layer of the first element. In some embodiments, the non-conductive material of the first element can be directly bonded to the corresponding non-conductive material of the second element using dielectric-to-dielectric bonding techniques. For example, dielectric-to-dielectric bonds may be formed without an adhesive using the direct bonding techniques disclosed at least in U.S. Pat. Nos. 9,564,414; 9,391,143; and 10,434,749, the entire contents of each of which are incorporated by reference herein in their entirety and for all purposes.

In various embodiments, hybrid direct bonds can be formed without an intervening adhesive. For example, dielectric bonding surfaces can be polished to a high degree of smoothness. The bonding surfaces can be cleaned and exposed to a plasma and/or etchants to activate the surfaces. In some embodiments, the surfaces can be terminated with a species after activation or during activation, e.g., during the plasma and/or etch processes. Without being limited by theory, in some embodiments, the activation process can be performed to break chemical bonds at the bonding surface, and the termination process can provide additional chemical species at the bonding surface that improves the bonding energy during direct bonding. In some embodiments, the activation and termination are provided in the same step, e.g., a plasma or wet etchant to activate and terminate the surfaces. In other embodiments, the bonding surface can be terminated in a separate treatment to provide the additional species for direct bonding. In various embodiments, the terminating species can comprise nitrogen. Further, in some embodiments, the bonding surfaces can be exposed to fluorine. For example, there may be one or multiple fluorine peaks near layer and/or bonding interfaces/surfaces. Thus, in some embodiments, in the directly bonded structures, the bonding interface between two dielectric materials can comprise a very smooth interface with higher nitrogen content and/or fluorine peaks at the bonding interface/surface. Additional examples of activation and/or termination treatments may be found throughout U.S. Pat. Nos. 9,564,414; 9,391,143; and 10,434,749, the entire contents of each of which are incorporated by reference herein in their entirety and for all purposes.

In various embodiments, conductive contact pads of the first element can also be directly bonded to corresponding conductive contact pads of the second element. For example, a hybrid bonding technique can be used to provide conductor-to-conductor direct bonds along a bond interface/surface that includes covalently direct bonded dielectric-to-dielectric surfaces, prepared as described above. In various embodiments, the conductor-to-conductor, e.g., contact pad to contact pad, direct bonds and the dielectric-to-dielectric hybrid bonds can be formed using the direct bonding techniques disclosed at least in U.S. Pat. Nos. 9,716,033 and 9,852,988, the entire contents of each of which are incorporated by reference herein in their entirety and for all purposes.

For example, dielectric bonding surfaces can be prepared and directly bonded to one another without an intervening adhesive as explained above. Conductive contact pads, which may be surrounded by non-conductive dielectric field regions, may also directly bond to one another without an intervening adhesive. In some embodiments, the respective contact pads can be recessed below exterior (e.g., upper) surfaces of the dielectric regions or non-conductive bonding regions, for example, recessed by less than 30 nm, less than 20 nm, less than 15 nm, or less than 10 nm, for example, recessed in a range of 2 nm to 20 nm, or in a range of 4 nm to 10 nm. The non-conductive bonding regions can be directly bonded to one another without an adhesive at room temperature in some embodiments and, subsequently, the bonded structure can be annealed. Upon annealing, the contact pads can expand and contact one another to form a metal-to-metal direct bond. Beneficially, the use of hybrid bonding techniques, such as Direct Bond Interconnect, or DBI®, available commercially from Xperi of San Jose, CA, can enable high density of pads connected across the direct bond interface/surface, e.g., small or fine pitches for regular arrays. In some embodiments, the pitch of the bonding pads, or conductive traces embedded in the bonding surface of one of the bonded elements, may be less 40 microns or less than 10 microns or even less than 2 microns. For some applications the ratio of the pitch of the bonding pads to one of the dimensions of the bonding pad is less than 5, or less than 3 and sometimes desirably less than 2. In other applications the width of the conductive traces embedded in the bonding surface of one of the bonded elements may range between 0.3 to 3 microns. In various embodiments, the contact pads and/or traces can comprise copper, although other metals may be suitable.

Thus, in direct bonding processes, a first element can be directly bonded to a second element without an intervening adhesive. In some arrangements, the first element can comprise a singulated element, such as a singulated integrated device die. In other arrangements, the first element can comprise a carrier or substrate (e.g., a wafer) that includes a plurality, e.g., tens, hundreds, or more, of device regions that, when singulated, form a plurality of integrated device dies. Similarly, the second element can comprise a singulated element, such as a singulated integrated device die. In other arrangements, the second element can comprise a carrier or substrate (e.g., a wafer).

As explained herein, the first and second elements can be directly bonded to one another without an adhesive, which is different from a deposition process. In one application, a width of the first element in the bonded structure can be similar to a width of the second element. In some other embodiments, a width of the first element in the bonded structure can be different from a width of the second element. The width or area of the larger element in the bonded structure may be at least 10% larger than the width or area of the smaller element. The first and second elements can accordingly comprise non-deposited elements. Further, directly bonded structures, unlike deposited layers, can include a defect region along the bond interface/surface in which nanovoids are present. The nanovoids may be formed due to activation of the bonding surfaces/interfaces, e.g., exposure to a plasma. As explained above, the bond interface/surface can include concentration of materials from the activation and/or last chemical treatment processes. For example, in embodiments that utilize a nitrogen plasma for activation, a nitrogen peak can be formed at the bond interface/surface. In embodiments that utilize an oxygen plasma for activation, an oxygen peak can be formed at the bond interface/surface. In some embodiments, the bond interface/surface can comprise silicon oxynitride, silicon oxycarbonitride, or silicon carbonitride. As explained herein, the direct bond can comprise a covalent bond, which is stronger than van Der Waals bonds. The bonding layers can also comprise polished surfaces that are planarized to a high degree of smoothness.

In some embodiments, metal-to-metal bonds are formed between contact pads. In some embodiments, the contact pads comprise copper or a copper alloy. In various embodiments, the metal-to-metal bonds between the contact pads can be joined such that copper grains grow into each other across the bond interface/surfaces. In some embodiments, the copper can have grains oriented along the 111 crystal plane for improved copper diffusion across the bond interface. The bond interface can extend substantially entirely to at least a portion of the bonded contact pads, such that there is substantially no gap between the non-conductive bonding regions at or near the bonded contact pads. In some embodiments, a barrier layer may be provided under the contact pads, e.g., which may include copper. In other embodiments, however, there may be no barrier layer under the contact pads, for example, as described in US 2019/0096741, which is incorporated by reference herein in its entirety and for all purposes.

### Additional Embodiments

In the foregoing specification, the systems and processes have been described with reference to specific embodiments thereof. It will, however, be evident that various modifications and changes may be made thereto without departing from the broader spirit and scope of the embodiments disclosed herein. The specification and drawings are, accordingly, to be regarded in an illustrative rather than restrictive sense.

Indeed, although the systems and processes have been disclosed in the context of certain embodiments and examples, it will be understood by those skilled in the art that the various embodiments of the systems and processes extend beyond the specifically disclosed embodiments to other alternative embodiments and/or uses of the systems and processes and obvious modifications and equivalents thereof. In addition, while several variations of the embodiments of the systems and processes have been shown and described in detail, other modifications, which are within the scope of this disclosure, will be readily apparent to those of skill in the art based upon this disclosure. It is also contemplated that various combinations or sub-combinations of the specific features and embodiments of the embodiments may be made and still fall within the scope of the disclosure. It should be understood that various features and embodiments of the disclosed embodiments can be combined with, or substituted for, one another in order to form varying modes of the embodiments of the disclosed systems and processes. Any methods disclosed herein need not be performed in the order recited. Thus, it is intended that the scope of the systems and processes herein disclosed should not be limited by the particular embodiments described above.

It will be appreciated that the systems and methods of the disclosure each have several innovative embodiments, no single one of which is solely responsible or required for the desirable attributes disclosed herein. The various features and processes described above may be used independently of one another or may be combined in various ways. All possible combinations and sub-combinations are intended to fall within the scope of this disclosure.

Certain features that are described in this specification in the context of separate embodiments also may be implemented in combination in a single embodiment. Conversely, various features that are described in the context of a single embodiment also may be implemented in multiple embodiments separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination. No single feature or group of features is necessary or indispensable to each and every embodiment.

It will also be appreciated that conditional language used herein, such as, among others, “can,” “could,” “might,” “may,” “for example,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. In addition, the term “or” is used in its inclusive sense (and not in its exclusive sense) so that when used, for example, to connect a list of elements, the term “or” means one, some, or all of the elements in the list. In addition, the articles “a,” “an,” and “the” as used in this application and the appended claims are to be construed to mean “one or more” or “at least one” unless specified otherwise. Similarly, while operations may be depicted in the drawings in a particular order, it is to be recognized that such operations need not be performed in the particular order shown or in sequential order, or that all illustrated operations be performed, to achieve desirable results. Further, the drawings may schematically depict one or more example processes in the form of a flowchart. However, other operations that are not depicted may be incorporated in the example methods and processes that are schematically illustrated. For example, one or more additional operations may be performed before, after, simultaneously, or between any of the illustrated operations. Additionally, the operations may be rearranged or reordered in other embodiments. Additionally, other embodiments are within the scope of the following claims. In some cases, the actions recited in the claims may be performed in a different order and still achieve desirable results.

Further, while the methods and devices described herein may be susceptible to various modifications and alternative forms, specific examples thereof have been shown in the drawings and are herein described in detail. It should be understood, however, that the embodiments are not to be limited to the particular forms or methods disclosed, but, to the contrary, the embodiments are to cover all modifications, equivalents, and alternatives falling within the spirit and scope of the various implementations described and the appended claims. Further, the disclosure herein of any particular feature, aspect, method, property, characteristic, quality, attribute, element, or the like in connection with an implementation or embodiment can be used in all other implementations or embodiments set forth herein. Any methods disclosed herein need not be performed in the order recited. The methods disclosed herein may include certain actions taken by a practitioner; however, the methods can also include any third-party instruction of those actions, either expressly or by implication. The ranges disclosed herein also encompass any and all overlap, sub-ranges, and combinations thereof. Language such as “up to,” “at least,” “greater than,” “less than,” “between,” and the like includes the number recited. Numbers preceded by a term such as “about” or “approximately” include the recited numbers and should be interpreted based on the circumstances (for example, as accurate as reasonably possible under the circumstances, for example ±5%, ±10%, ±15%, etc.). For example, “about 3.5 mm” includes “3.5 mm.” Phrases preceded by a term such as “substantially” include the recited phrase and should be interpreted based on the circumstances (for example, as much as reasonably possible under the circumstances). For example, “substantially constant” includes “constant.” Unless stated otherwise, all measurements are at standard conditions including temperature and pressure.

As used herein, a phrase referring to “at least one of” a list of items refers to any combination of those items, including single members. As an example, “at least one of: A, B, or C” is intended to cover: A, B, C, A and B, A and C, B and C, and A, B, and C. Conjunctive language such as the phrase “at least one of X, Y and Z,” unless specifically stated otherwise, is otherwise understood with the context as used in general to convey that an item, term, etc. may be at least one of X, Y or Z. Thus, such conjunctive language is not generally intended to imply that certain embodiments require at least one of X, at least one of Y, and at least one of Z to each be present. The headings provided herein, if any, are for convenience only and do not necessarily affect the scope or meaning of the devices and methods disclosed herein.

Accordingly, the claims are not intended to be limited to the embodiments shown herein but are to be accorded the widest scope consistent with this disclosure, the principles and the novel features disclosed herein.

1. A method comprising:
providing a first wafer and a second wafer;
polishing the first wafer and the second wafer;
dicing the first wafer on a dicing tape to form a diced wafer comprising a plurality of dies;
activating at least one of the first wafer, the diced wafer, and the second wafer;
flipping the diced wafer;
securing the diced wafer to a chuck;
removing the dicing tape from the diced wafer; and
bonding at least some of the dies of the plurality of dies to the second wafer.

2. The method of claim 1, wherein activating comprises activating the second wafer and one of the first wafer and the diced wafer.

3. The method of claim 1, wherein activating comprises exposing the at least one of the first wafer, the diced wafer, and the second wafer to a nitrogen plasma.

4. A method comprising:
providing a plurality of semiconductor dies on a dicing tape, each semiconductor die of the plurality of semiconductor dies having a first bonding surface and a second surface opposite the first bonding surface, the second surfaces of the plurality of semiconductor dies being attached to the dicing tape; and
securing the first bonding surfaces of the plurality of semiconductor dies to a chuck while the plurality of semiconductor dies are attached to the dicing tape.

5.-7. (canceled)

8. The method of claim 4, further comprising:
removing the dicing tape from the plurality of semiconductor dies;
removing a semiconductor die of the plurality of semiconductor dies from the chuck; and
directly bonding the first bonding surface of the semiconductor die to a carrier without an intervening adhesive.

9.-10. (canceled)

11. The method of claim 8, wherein the directly bonding comprises directly bonding a non-conductive layer of the semiconductor die to a non-conductive layer of the carrier.

12. The method of claim 11, wherein the directly bonding further comprises directly bonding conductive contacts of the semiconductor die to conductive contacts of the carrier.

13. (canceled)

14. The method of claim 8, wherein the second surface is a second bonding surface, further comprising:
after the directly bonding, directly bonding a second semiconductor die to the second bonding surface of the semiconductor die.

15. The method of claim 4, further comprising:
removing the dicing tape from the plurality of semiconductor dies; and
selectively releasing one or more semiconductor dies of the plurality of semiconductor dies while the remaining semiconductor dies of the plurality of semiconductor dies are secured to the chuck.

16. (canceled)

17. The method of claim 4, wherein the chuck is an electrostatic chuck, and wherein securing comprises:
applying, by the electrostatic chuck, an electrostatic force to the plurality of semiconductor dies, wherein applying an electrostatic force comprises suppling power to a plurality of electrodes embedded in the electrostatic chuck.

18. The method of claim 17, further comprising:
removing the dicing tape from the plurality of semiconductor dies; and
selectively releasing one or more semiconductor dies of the plurality of semiconductor dies while the remaining semiconductor dies of the plurality of semiconductor dies are secured to the electrostatic chuck, wherein selectively releasing comprises changing the power supplied to one or more electrodes of the plurality of electrodes.

19. (canceled)

20. The method of claim 4, wherein the chuck is a vacuum chuck, and wherein securing comprises:
applying a vacuum force to the plurality of semiconductor dies via a plurality of vacuum channels embedded in the vacuum chuck.

21. The method of claim 20, further comprising:
removing the dicing tape from the plurality of semiconductor dies; and
selectively releasing one or more semiconductor dies of the plurality of semiconductor dies while the remaining semiconductor dies of the plurality of semiconductor dies are secured to the vacuum chuck.

22. The method of claim 21, wherein selectively releasing comprises reducing a vacuum force applied to the one or more semiconductor dies.

23. The method of claim 20, wherein a plurality of porous inserts are disposed on top of the plurality of vacuum channels.

24. The method of claim 23, wherein the plurality of semiconductor dies are disposed on top of the plurality of porous inserts.

25.-30. (canceled)

31. The method of claim 4, further comprising picking, by a vacuum bonding tool, a die of the plurality of dies from the chuck, wherein the vacuum bonding tool is conductive and electrically grounded, and wherein picking comprises removing a charge from the die by contacting the die with the conductive vacuum bonding tool.

32. A method comprising:
securing a wafer on a dicing tape;
dicing the wafer into a plurality of semiconductor dies, each semiconductor die of the plurality of semiconductor dies having a first bonding surface and a second surface opposite the first bonding surface, the second surfaces of the plurality of semiconductor dies being attached to the dicing tape;
securing the first bonding surfaces of the plurality of semiconductor dies to a chuck while the plurality of semiconductor dies are attached to the dicing tape;
removing the dicing tape from the plurality of semiconductor dies; and
removing a die of the plurality of semiconductor dies from the chuck.

33. The method of claim 32, further comprising flipping the plurality of semiconductor dies and the dicing tape.

34. The method of claim 32, wherein the chuck is an electrostatic chuck, the method further comprising:
applying an electrostatic force to the plurality of semiconductor dies for securing the plurality of semiconductor dies to the electrostatic chuck.

35. The method of claim 34, wherein removing the die comprises reducing the electrostatic force applied to the die by the electrostatic chuck.

36. The method of claim 34, wherein removing the die comprises terminating power supplied to one or more electrodes of the electrostatic chuck associated with the die.

37. The method of claim 34, wherein removing a die comprises inverting the electrostatic force applied by the electrostatic chuck to the die and reducing the electrostatic force applied by the electrostatic chuck to the die.

38.-46. (canceled)
